(19) United States
(12) Patent Application Publication
(10) Pub. No.: US 2013/0000703 A1
(43) Pub. Date: Jan. 3, 2013

(54) COMPLEX DYE-SENSITIZED PHOTOVOLTAIC APPARATUS

(75) Inventors: Kun-Mu Lee, Yunlin County (TW); Hsin-Wei Chen, Taipei City (TW); Chih-Yu Hsu, Taoyuan County (TW); Kuo-Chuan Ho, New Taipei City (TW); Wen-Hsiang Yen, Hsinchu City (TW)

(73) Assignee: INDUSTRIAL TECHNOLOGY RESEARCH INSTITUTE, HSINCHU (TW)

(21) Appl. No.: 13/310,640

(22) Filed: Dec. 2, 2011

(30) Foreign Application Priority Data
Jun. 28, 2011 (TW) TW100122584

(51) Int. Cl. H01L 31/04

(52) U.S. Cl. 136/252

(57) ABSTRACT

An embodiment of the invention provides a complex dye-sensitized photovoltaic apparatus including a conductive substrate, a counter electrode, a partition member, a photoelectric conversion layer, a first electrolyte, and a charge storage device or an electrochromic solution. A space is provided between the counter electrode and the conductive substrate. The partition member is disposed in the space, dividing the space into a first chamber and a second chamber. The photoelectric conversion layer is disposed on the conductive substrate in the first chamber filled with the first electrolyte, wherein the photoelectric conversion layer includes a porous semiconductor film and a dye absorbed on the porous semiconductor film. The photoelectric conversion layer and the conductive substrate form a working electrode. The charge storage device or the electrochromic solution is disposed in the second chamber.

### CROSS REFERENCE TO RELATED APPLICATIONS

This Application claims priority of Taiwan Patent Application No. 100122584, filed on Jun. 28, 2011, the entirety of which is incorporated by reference herein.

### BACKGROUND OF THE INVENTION

1. Field of the Invention

The present invention relates to photoelectric devices, and in particular relates to complex dye-sensitized photovoltaic apparatuses.

2. Description of the Related Art

Although conventional electrochromic devices may be used as a smart window glass with energy saving and may be applied to green buildings, external power must be supplied to the electrochromic devices to change the color thereof, which consumes energy.

In recent years, the concept of energy saving has progressively gotten more attention, wherein the combination of solar cells and electrochromic devices look to be a new trend, such as applications in building-integrated photovoltaic (BIPV) systems. Without need to supply external power, the building-integrated photovoltaic system can automatically adjust color intensity of electrochromic windows according to the variation of outdoor light intensity so as to reduce indoor thermal energy, thus achieving energy saving.

FIG. 1 is a cross-sectional view of a conventional hybrid apparatus combining a solar cell and an electrochromic device together. Referring to FIG. 1, the conventional hybrid apparatus 100 has a conductive substrate 110, a counter electrode 120, a photoelectric conversion layer 130, an electrochromic layer 140, and a hybrid electrolyte solution 150, wherein the conductive substrate 110 is opposite to the counter electrode 120, and a space V is provided therebetween.

The photoelectric conversion layer 130 is disposed on the conductive substrate 110, and the electrochromic layer 140 is disposed on the counter electrode 120. The hybrid electrolyte solution 150 fills the space V, wherein the hybrid electrolyte solution 150 includes an electrolyte for operation of solar cells and another electrolyte for operation of electrochromic devices, which enables oxidation-reduction reactions to occur at the photoelectric conversion layer 130 and the electrochromic layer 140.

However, because there are two electrolytes used for different purposes mixed in the hybrid electrolyte solution 150, the hybrid electrolyte solution 150 is not the best suited for both of the photoelectric conversion layer 130 and the electrochromic layer 140, which results in poor performance of photoelectric conversion and electrochromism. Furthermore, the photoelectric conversion layer 130 overlaps the electrochromic layer 140 (i.e. environmental light passes through the photoelectric conversion layer 130 and the electrochromic layer 140 sequentially), which lowers the maximum transmittance of the hybrid apparatus 100, and thus the color change of the electrochromic layer 140 is not obvious.

### BRIEF SUMMARY OF THE INVENTION

An embodiment of the invention provides a complex dye-sensitized photovoltaic apparatus which includes: a conductive substrate; a counter electrode opposite to the conductive substrate, wherein a space is provided between the counter electrode and the conductive substrate; a partition member disposed between the conductive substrate and the counter electrode, dividing the space into a plurality of independent chambers including at least a first chamber and a second chamber, wherein the partition member comprises an insulating material; a photoelectric conversion layer disposed on the conductive substrate in the first chamber, wherein the photoelectric conversion layer includes a porous semiconductor film and a dye absorbed on the porous semiconductor film, wherein the photoelectric conversion layer and the conductive substrate form a working electrode; a first electrolyte filled in the first chamber; and a first charge storage device or a first electrochromic solution located in the second chamber, wherein the first charge storage device includes a first charge storage layer and a second electrolyte, wherein the first charge storage layer is disposed on at least one of the conductive substrate and the counter electrode, and the second electrolyte fills the second chamber to contact with the first charge storage layer, provided that the second electrolyte is different from the first electrolyte, or the first electrochromic solution fills the second chamber to contact with the conductive substrate and the counter electrode, provided that the first electrochromic solution is different from the first electrolyte.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a cross-sectional view of a conventional hybrid apparatus combining a solar cell and an electrochromic device together;

FIG. 2 is a cross-sectional view of a complex dye-sensitized photovoltaic apparatus of an embodiment of the invention;

FIG. 3 is a top view of the complex dye-sensitized photovoltaic apparatus in FIG. 2, wherein FIG. 2 is a cross-sectional view along the line I-I in FIG. 3;

FIG. 4 and FIG. 5 are top views of a process for forming a complex dye-sensitized photovoltaic apparatus of an embodiment of the invention;

FIG. 6 is a cross-sectional view of a complex dye-sensitized photovoltaic apparatus of another embodiment of the invention;

FIG. 7 is a cross-sectional view of a complex dye-sensitized photovoltaic apparatus of still another embodiment of the invention;

FIG. 8 is a top view of the complex dye-sensitized photovoltaic apparatus in FIG. 7, wherein FIG. 7 is a cross-sectional view along the line I-I in FIG. 8;

FIG. 9 is a cross-sectional view of a complex dye-sensitized photovoltaic apparatus of another embodiment of the invention;

FIG. 10 is a cross-sectional view of a complex dye-sensitized photovoltaic apparatus of an embodiment of the invention;

FIG. 11 is a top view of the complex dye-sensitized photovoltaic apparatus in FIG. 10, wherein FIG. 10 is a cross-sectional view along the line I-I in FIG. 11;

FIG. 12 is a cross-sectional view of a complex dye-sensitized photovoltaic apparatus of an embodiment of the invention;

FIG. 13 is a top view of the complex dye-sensitized photovoltaic apparatus in FIG. 12, wherein FIG. 12 is a cross-sectional view along the line I-I in FIG. 13;

FIG. 14 is a current-voltage character curve (I-V curve) diagram of the dye-sensitized solar cell of the complex dye-sensitized photovoltaic apparatus of FIG. 2; and

FIG. 15 is a diagram illustrating the transmittance variation of the charge storage device (the electrochromic device) of the complex dye-sensitized photovoltaic apparatus of FIG. 2.

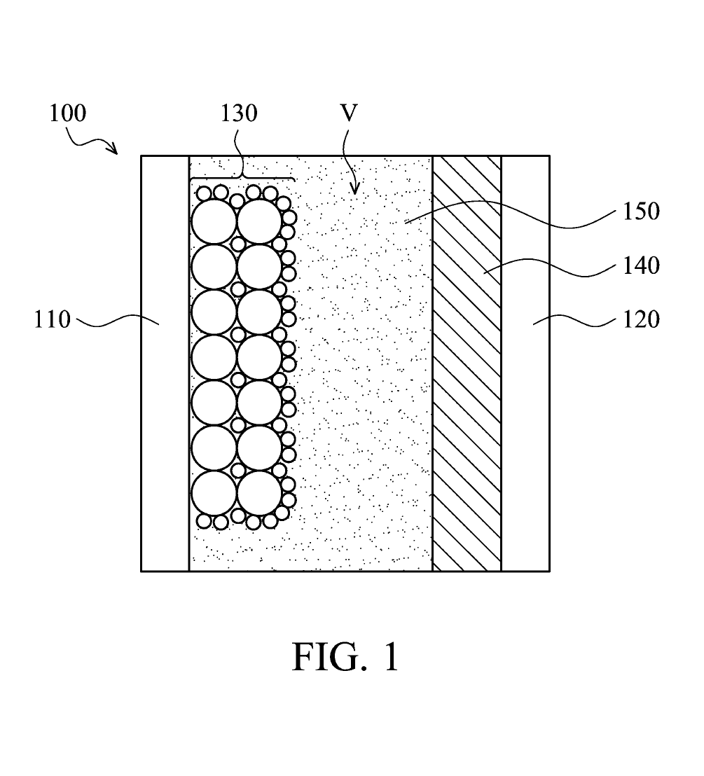

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

It is understood, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

In the present invention, a partition member is disposed in a space provided between a conductive substrate and a counter electrode, so as to divide the space into a plurality of independent cambers, and thus a dye-sensitized solar cell device (a photoelectric conversion layer and an exclusive electrolyte thereof) and a charge storage device (a charge storage layer and an exclusive electrolyte thereof) or an electrochromic solution are disposed in the different chambers respectively. Therefore, each of the devices mentioned above has the best suited electrolyte, which improves efficiency of each of the devices, wherein the efficiency includes photoelectric conversion efficiency, electrochromic effect, and charge storage.

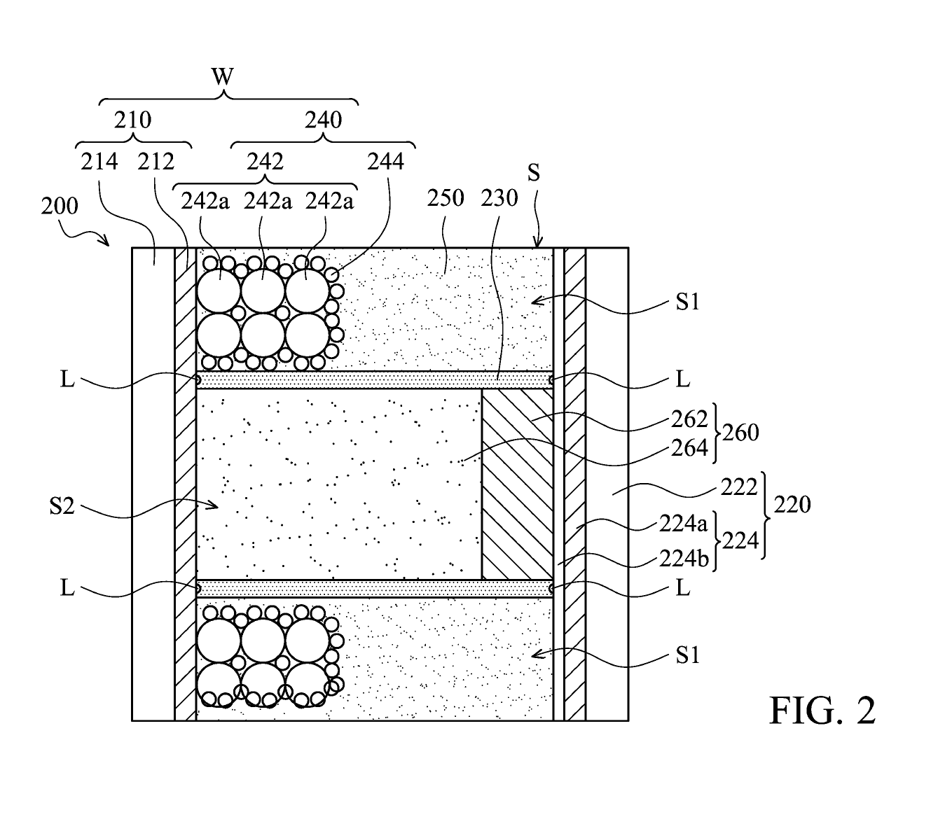

FIG. 2 is a cross-sectional view of a complex dye-sensitized photovoltaic apparatus of an embodiment of the invention. Referring to FIG. 2, in the present embodiment, the complex dye-sensitized photovoltaic apparatus 200 includes a conductive substrate 210, a counter electrode 220, a partition member 230, a photoelectric conversion layer 240, a first electrolyte solution 250, and a first charge storage device 260.

In one embodiment, the conductive substrate 210 may be a base 214, wherein a conductive layer 212 is deposited on a surface of the base 214. The base 214 may be a transparent base, such as a glass substrate or a plastic substrate including polyethylene terephthalate (PET), polyethylene nathphalate (PEN), polycarbonate (PC), or polyimide (PI). The conductive layer 212 includes, for example, transparent conducting oxides (TCO), such as fluorine-doped tin oxides (FTO, SnO₂:F), indium tin oxides (ITO), indium zinc oxides (IZO), aluminum-doped zinc oxides (AZO) or conductive polymers, such as poly(3,4-ethylenedioxythiophene) (PEDOT), PPropOT-Et₂ (poly(3,3-diethyl-3,4-dihydro-2H-thieno-[3,4-b][1,4]dioxepine)), or polyaniline. Alternatively, the conductive layer 212 may include metal (e.g. titanium, stainless steel, or aluminum) or carbon (e.g. graphene, or carbon nanotubes). In another embodiment, the conductive substrate 210 may be a substrate formed from a conductive material, such as a metal (e.g. titanium).

The counter electrode 220 is oppositely disposed to the conductive substrate 210, and a space S is provided therebetween. In one embodiment, the counter electrode 220 includes a substrate 222 and a conductive layer 224 deposited thereon. The substrate 222 may be a transparent substrate including, for example, glass or plastics, such as polyethylene terephthalate, polyethylene nathphalate, polycarbonate, or polyimide.

The conductive layer 224 includes metal, carbon, conductive polymers, transparent conductive oxides, or combinations thereof. The transparent conductive oxides are, for example, fluorine-doped tin oxides, indium tin oxides, indium zinc oxides, or aluminum-doped zinc oxides. The conductive polymers are, for example, poly(3,4-ethylenedioxythiophene) (PEDOT), PPropOT-Et₂ (poly(3,3-diethyl-3,4-dihydro-2H-thieno-[3,4-b][1,4]dioxepine)), or polyaniline. In the present embodiment, a transparent conductive oxide layer 224a and a platinum layer 224b are sequentially formed on the substrate 222, wherein the platinum layer 224b has a good conductivity and does not react with the electrolyte solution, and the transparent conductive oxide layer 224a and the platinum layer 224b constitute the conductive layer 224.

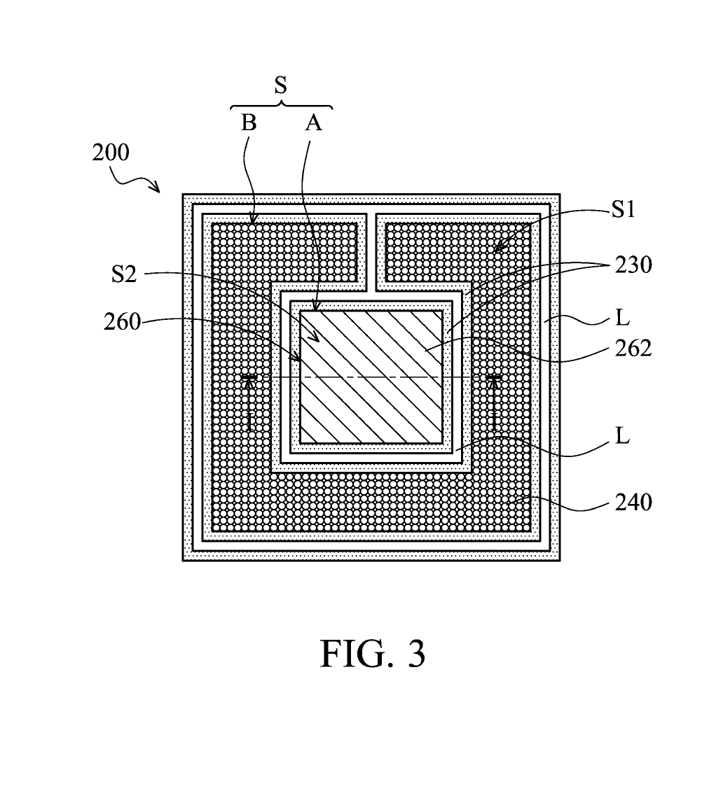

FIG. 3 is a top view of the complex dye-sensitized photovoltaic apparatus in FIG. 2, wherein FIG. 2 is a cross-sectional view along the line I-I in FIG. 3. It should be noted that, because a transparent conductive substrate is taken as an example in the embodiment of FIG. 2, the devices under the conductive substrate are visible from the top view (i.e. FIG. 3), and thus the devices under the conductive substrate are depicted with solid lines in FIG. 3.

Referring to FIGS. 2 and 3, the partition member 230 is disposed between the conductive substrate 210 and the counter electrode 220, and divides the space S into a plurality of independent chambers including a first chamber S1 and a second chamber S2. The partition member 230 includes insulating materials, such as polymer materials or other materials with a good insulating property which do not react with the electrolyte solutions.

In one embodiment, the photoelectric conversion layer 240 is disposed on the conductive substrate 210 and in the first chamber S1, wherein the photoelectric conversion layer 240 and the conductive substrate 210 together constitute a working electrode W. The photoelectric conversion layer 240 includes a porous semiconductor layer 242 and a dye 244 absorbed on the porous semiconductor layer 242. As shown in FIG. 2, in one embodiment, the porous semiconductor layer 242 is a film formed from a plurality of semiconductor particles 242a, and the dye 244 is absorbed on the semiconductor particles 242a, wherein the semiconductor particles 242a includes, for example, titanium dioxides (TiO₂), zinc oxides (ZnO), aluminum oxides (Al₂O₃), nickel oxides (NiO), or tin dioxides (SnO₂).

The dye 244 is a photosensitive dye including metal complexes of ruthenium, osmium, iron, illinium, platinum, or zinc, or the photosensitive dye is an organic dye, such as porphyrin, phthalocyanine, coumarin, cyanine, or hemicyanine, wherein the commonly used photosensitive dye is a ruthenium metal complex.

Commercially available ruthenium metal complexes include a N3 dye, a N712 dye, a N719 dye, or a N749 dye. The chemical formula of the N3 dye is cis-di(thiocyanato)-bis(2,2′-bipyridyl-4,4-dicarboxylic acid)-ruthenium (II). The chemical formula of the N712 dye is (Bu₄N) 4-[Ru (dcbpy) 2 (NCS) 2], wherein Bu₄N is tetrabutyl-ammonium, and dcbpy H₂ is 2,2′-bipyridyl-4,4′-dicarboxylic acid. The chemical formula of the N719 dye is cis-di(thiocyanato)-bis(2,2′-bipyridyl-4-carboxylate-4′-carboxylic acid)-ruthenium (II). The chemical formula of the N749 dye is (4,4′,4′-tricarboxy-2,2′:6′,2′-terpyridine) ruthenium (II).

The first electrolyte solution 250 fills the first chamber S1 to contact with the photoelectric conversion layer 240. The first electrolyte solution 250 includes redox pairs, such as the redox pairs constituted by iodide ions (I⁻) and triiodide ions (I₃⁻). The first electrolyte solution 250 may be prepared, for example, by dissolving ionic compounds suitable to form the redox pairs in the solvent.

The ionic compounds include halides, such as iodides or bromides. Specifically, metal iodide salts or metal bromide salts may be used. The ionic compound capable of forming iodide ions (E) and triiodide ions (I₃⁻) is preferred, such as LiI, KI, and KI₃. In one embodiment, LiI and I₂ are dissolved in the solvent to form a I⁻/I₃⁻ redox pair. The solvent is, for example, methoxypropionitrile (MPN), acetonitrile (AN), or γ-butyrolactone (GBL).

In one embodiment, the first electrolyte solution 250 has 0.1M LiI dissolved in acetonitrile, a 0.05M I₂, a 0.6M 1,2-dimethyl-3-propylimi-dazolium iodide (DMPII), and a 0.5M 4-tert-butylpyridine (TBP).

The first charge storage device 260 is located in the second chamber S2, wherein the first charge storage device 260 includes a first charge storage layer 262 and a second electrolyte solution 264. The first charge storage layer 262 is disposed on at least one of the conductive substrate 210 and the counter electrode 220. In other words, according to materials, properties, or uses, the first charge storage layer 262 may be disposed on one of the conductive substrate 210 and the counter electrode 220, or on both the conductive substrate 210 and the counter electrode 220. The second electrolyte solution 264 fills the second chamber S2 to contact with the first charge storage layer 262, wherein the second electrolyte solution 264 enables an electrochromic reaction or a charge storage reaction to occur at the first charge storage layer 262 of the first charge storage device 260, and the material of the second electrolyte solution 264 is different from that of the first electrolyte solution 250 of the dye-sensitized solar cell.

For example, in one embodiment, the first charge storage device 260 is a capacitor device, and the first charge storage layer 262 is a capacitor electrode. In this case, the first charge storage layer 262 may be disposed on the conductive substrate 210 (not shown), the counter electrode 220 (as shown in FIG. 2), or both the conductive substrate 210 and the counter electrode 220 (not shown) according to the requirements of capacitance or arrangement.

The capacitor electrode includes, for example, conductive polymers, carbon materials, or other suitable capacitor materials. The conductive polymers are, for example, poly(3,4-ethylenedioxythiophene) (PEDOT), PPropOT-Et₂ (poly(3,3-diethyl-3,4-dihydro-2H-thieno-[3,4-b][1,4]dioxepine)), or polyaniline. The carbon materials are, for example, activated carbon, carbon nanotubes, or graphene. If the first charge storage layer 262 is a capacitor electrode, the second electrolyte solution 264 is, for example, a sulfuric acid solution.

In another embodiment, the first charge storage device 260 is an electrochromic device, and the first charge storage layer 262 is an electrochromic material layer. In this case, the first charge storage layer 262 may be disposed on the conductive substrate 210 (not shown), the counter electrode 220 (as shown in FIG. 2), or both the conductive substrate 210 and the counter electrode 220 (not shown) according to the requirements of the size or the arrangement of the electrochromic material layer.

The electrochromic material layer may include conductive polymers, organic molecules, inorganic materials, or other suitable electrochromic materials. The conductive polymers are, for example, poly(3,4-ethylenedioxythiophene) (PEDOT), PPropOT-Et₂ (poly(3,3-diethyl-3,4-dihydro-2H-thieno-[3,4-b][1,4]dioxepine)), polyaniline, or polypyrrole. The organic molecules are, for example, viologen (1,1′-disubstituted-4,4′-bipyridilium). The inorganic materials are, for example, Prussian blue (iron(III) hexacyanoferrate), WO₃, or V₂O₅.

In one embodiment, the material of the electrochromic material layer mentioned above is the same as that of the conductive layer 224, and they are both conductive polymers, such as poly(3,4-ethylenedioxythiophene) (PEDOT), PPropOT-Et₂ (poly(3,3-diethyl-3,4-dihydro-2H-thieno-[3,4-h][1,4]dioxepine)), or polyaniline.

Furthermore, if the first charge storage layer 262 is an electrochromic material layer, the second electrolyte solution 264 includes, for example, a 1.0M tetrabutylammonium bromide (TBABr) dissolved in 3-methoxypropionitrile, 0.1M LiClO₄, and 0.004M Br₂.

It should be noted that, because the partition member 230 separates the first electrolyte solution 250 from the second electrolyte solution 264 of the first charge storage device 260 in the embodiment, the most suitable first electrolyte solution 250 and the most suitable second electrolyte solution 264 may be chosen for the photoelectric conversion layer 240 and the first charge storage layer 262 respectively, thereby effectively improving performance of the photoelectric conversion layer 240 and the first charge storage layer 262.

Furthermore, because the photoelectric conversion layer 240 and the first charge storage device 260 are located in different chambers respectively, the photoelectric conversion layer 240 does not overlap with the first charge storage device 260, which may effectively raise the maximum transmittance of the complex dye-sensitized photovoltaic apparatus 200, thereby improving the color change effect of the electrochromic layer.

In one embodiment, the complex dye-sensitized photovoltaic apparatus 200 may further include a high-conductivity structure L. A portion of the high-conductivity structure L is on the conductive substrate 210 and sandwiched between the partition member 230 and the conductive substrate 210, and another portion of the high-conductivity structure L is on the counter electrode 220 and sandwiched between the partition member 230 and the counter electrode 220.

Specifically, the partition member 230 covers the high-conductivity structure L to prevent the high-conductivity structure L from contacting with the first electrolyte solution 250 and the second electrolyte solution 264, wherein the high-conductivity structure L has an electric conductivity higher than the conductive substrate 210 or the counter electrode 220. The high-conductivity structure L includes silver, copper, aluminum, copper aluminum alloys, or other materials with good conductive properties. The high-conductivity structure L may effectively collect the charges produced by the photoelectric conversion layer 240, and uniformly conduct the charges to the first charge storage device 260.

One of the manufacturing methods of the complex dye-sensitized photovoltaic apparatus 200 mentioned above is described as follows, and the experiment parameters and the material of the devices described below are merely examples and are not intended to be limiting.

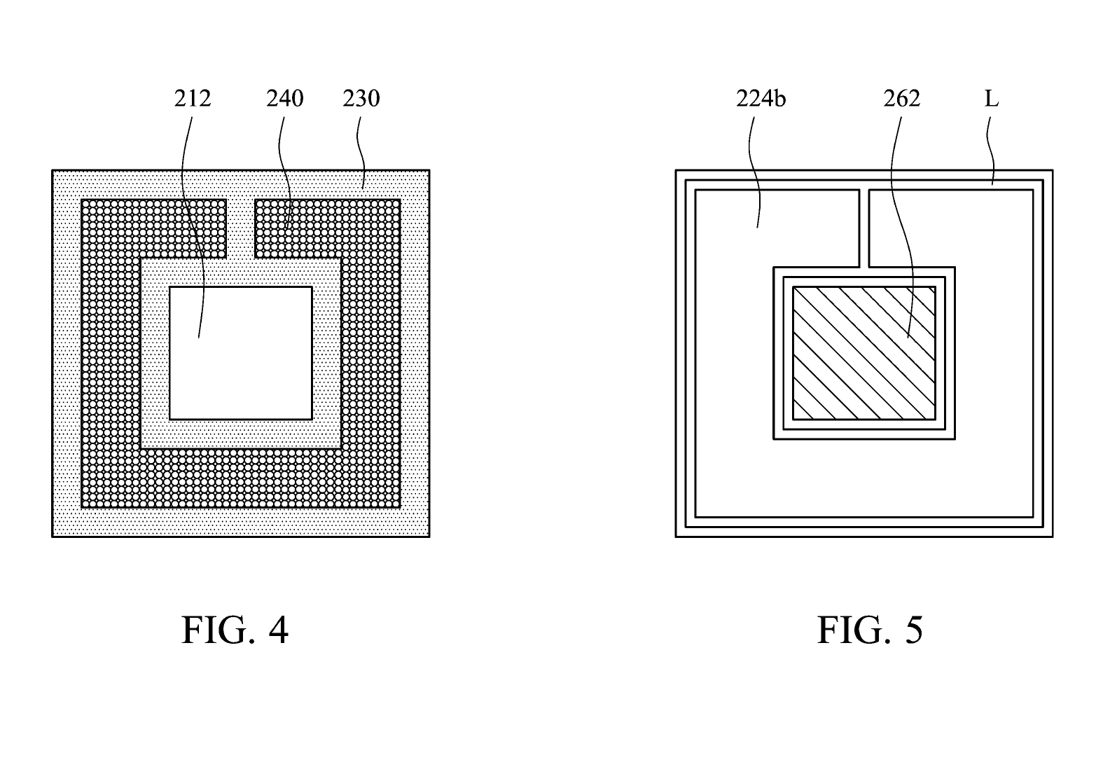

FIG. 4 and FIG. 5 are top views of a process for forming a complex dye-sensitized photovoltaic apparatus of an embodiment of the invention. Firstly, referring to FIG. 4, a base is provided, and a conductive layer 212 is formed on the base to form a conductive substrate. Then, a mask is formed on the conductive layer 212 of the conductive substrate to shield the portion of the conductive layer 212 which is not directed to form a photoelectric conversion layer thereon. Then, a titania paste layer is formed on a portion of the conductive layer 212 of the conductive substrate by screen printing, scraper coating, or other suitable methods. Then, the mask is removed.

Then, the conductive substrate with the titania paste layer is disposed in an oven, for example, at 450° C. to be sintered, so as to form TiO₂ particle layer on the conductive substrate. Then, the conductive substrate with TiO₂ particle layer is dipped in a solution containing dye to absorb the dye, and the preferred absorption time is 24 hours, wherein the dye includes, for example, N719 from Solaronix. The TiO₂ particle layer with the dye absorbed thereon may serve as a photoelectric conversion layer 240.

Then, referring to FIG. 5, a fluorine-doped tin oxide conductive glass is provided, and a platinum layer 224b is formed thereon by a thermal reduction to form a counter electrode. The process conditions of the thermal reduction include, for example: dispersing a 7.5 mM platinum precursor (H₂PtCl₆) in terpineol to perform a screen printing process, and then performing high temperature sintering (at 400° C.) to form a transparent platinum counter electrode with an island structure.

Then, an electroplating solution used to electroplate an electrochromic material layer is prepared, wherein the electroplating solution contains a 10 mM 3,3-diethyl-3,4-dihydro-2H-thieno-[3,4-b][1,4]dioxepine (PropOT-Et₂) monomer dissolved in acetonitrile and a 100 mM LiClO₄.

Then, a mask is formed on the platinum layer 224b to shield a portion of the platinum layer 224b which is not to be electroplated. Then, the counter electrode is disposed in an electroplating solution to perform an electroplating process, wherein the electroplating conditions include, for example: depositing a conductive polymer film on the platinum layer 224b at 1.2V (vs. Ag/Ag⁺) to serve as a first charge storage layer 262 (i.e. the electrochromic material layer), wherein the electrical quantity of the electroplating process is 40 mC/cm². Then, the mask is removed.

Then, referring to FIG. 4 and FIG. 5, a partition member 230 may be optionally formed on the conductive substrate (or the counter electrode), and the partition member 230 surrounds the photoelectric conversion layer 240 (or the first charge storage layer 262). Furthermore, before forming the partition member 230, a portion of the high-conductivity structure L (as shown in FIG. 2) may be formed on the conductive substrate in advance, and then the partition member 230 may be formed, wherein the partition member 230 covers the portion of the high-conductivity structure L. Moreover, another portion of the high-conductivity structure L may be formed on the partition member 230 or the counter electrode. In FIG. 5, the another portion of the high-conductivity structure L is formed on the counter electrode.

Then, referring to FIG. 2 and FIG. 3, the conductive substrate is bonded to the counter electrode. In this case, the partition member 230 is placed between the conductive substrate 210 and the counter electrode 220 so as to divide the space between the conductive substrate 210 and the counter electrode 220 into a first chamber S1 and a second chamber S2, wherein the first chamber S1 accommodates the photoelectric conversion layer 240, and the second chamber S2 accommodates the first charge storage layer 262. A portion of the high-conductivity structure L is sandwiched between the partition member 230 and the conductive substrate, and another portion of the high-conductivity structure L is sandwiched between the partition member 230 and the counter electrode.

Then, an electrolyte solution (the first electrolyte solution 250) used in dye-sensitized solar cells and an electrolyte (the second electrolyte solution 264) used in electrochromic devices are injected into the first chamber S1 and the second chamber S2 respectively, and then the injection holes of the first chamber S1 and the second chamber S2 are sealed by encapsulating materials.

As shown in FIG. 3, in one embodiment, the space S includes a center area A and a peripheral area B surrounding the center area A. The first chamber S1 is located in the peripheral area B, and the second chamber S2 is located in the center area A. The first charge storage device 260 is an electrochromic device, and the photoelectric conversion layer 240 surrounds the electrochromic device.

In this case, the complex dye-sensitized photovoltaic apparatus 200 serves as, for example, a smart window, and the photoelectric conversion layer 240 may be on the periphery of the window. If environmental light illuminates the photoelectric conversion layer 240, the photoelectric conversion layer 240 may produce a current to change the color of the first charge storage device 260 in the center area of the window, which adjusts indoor brightness and temperature.

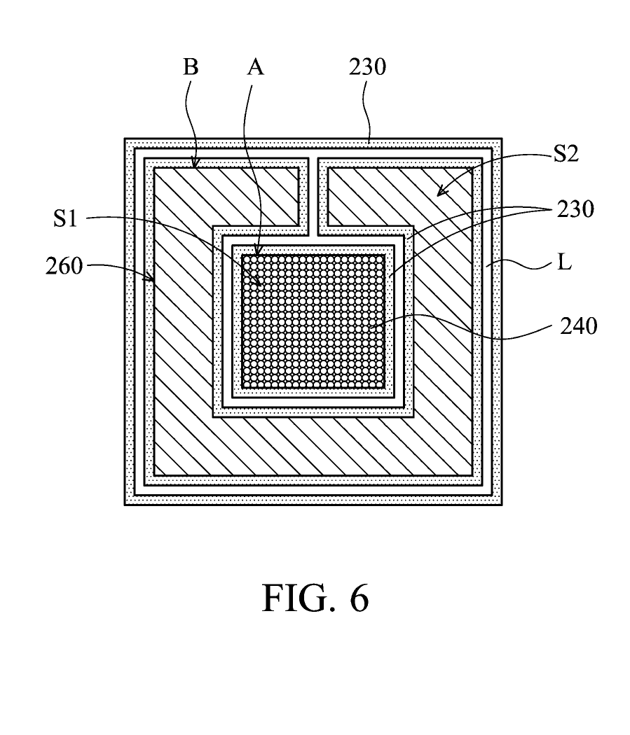

FIG. 6 is a cross-sectional view of a complex dye-sensitized photovoltaic apparatus of another embodiment of the invention. In another embodiment, as shown in FIG. 6, the positions of the electrochromic device (the first charge storage device 260) and the photoelectric conversion layer 240 may be exchanged, such that the electrochromic device surrounds the photoelectric conversion layer 240.

Specifically, the positions of the first chamber S1 and the second chamber S2 may be exchanged, such that the first chamber S1 accommodating the photoelectric conversion layer 240 is located in the center area A, and the second chamber S2 accommodating the electrochromic device is located in the peripheral area B.

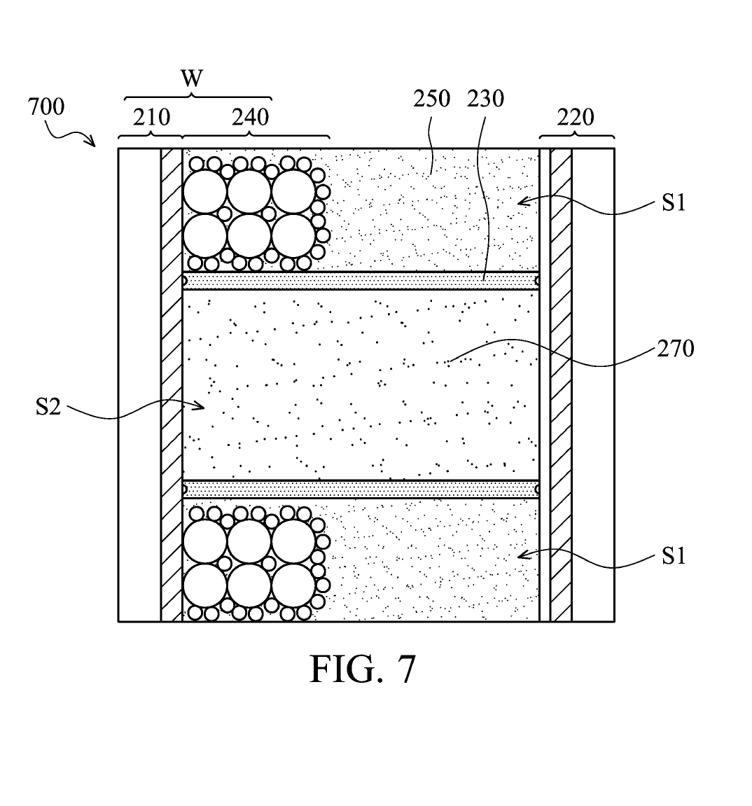

FIG. 7 is a cross-sectional view of a complex dye-sensitized photovoltaic apparatus of still another embodiment of the invention. Referring to FIG. 7, the complex dye-sensitized photovoltaic apparatus 700 of the present embodiment is similar to the complex dye-sensitized photovoltaic apparatus 200 of FIG. 2, and the difference therebetween is that the electrochromic material of the complex dye-sensitized photovoltaic apparatus 700 is dissolved in the electrolyte solution to form a first electrochromic solution 270. The first electrochromic solution 270 fills the second chamber S2 to contact with the conductive substrate 210 and the counter electrode 220, and the first electrochromic solution 270 is different from the first electrolyte solution 250.

The first electrochromic solution 270 includes electrochromic materials and solvents. The electrochromic materials are, for example, methyl viologen, ethyl viologen, heptyl viologen (HV), benzyl viologen, propyl viologen, dimethylphenazine, phenylene diamine, N,N,N′,N′-tetramethyl-1,4-phenylenediamine (TMPD), and redox potentials thereof are both less than 3V. The solvent of the first electrochromic solution 270 is, for example, propylene carbonate, glycol carbonate, γ-butyrolactone, acetonitrile, tetrahydrofuran, or N-methylpyrrolidinone (NMP).

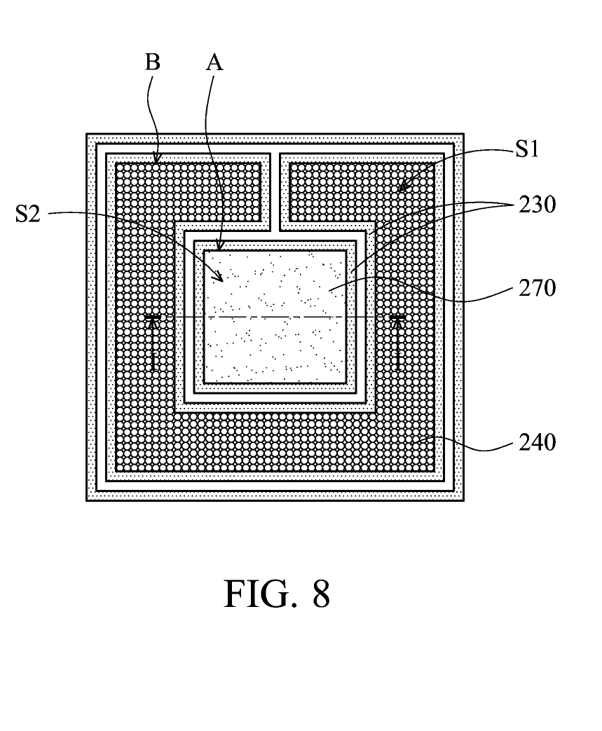

FIG. 8 is a top view of the complex dye-sensitized photovoltaic apparatus in FIG. 7, wherein FIG. 7 is a cross-sectional view along the line I-I in FIG. 8. Referring to FIG. 7 and FIG. 8, in the embodiment, the first chamber S1 accommodating the photoelectric conversion layer 240 is located in the peripheral area B, and the second chamber S2 accommodating the first electrochromic solution 270 is located in the center area A. Therefore, the photoelectric conversion layer 240 surrounds the first electrochromic solution 270.

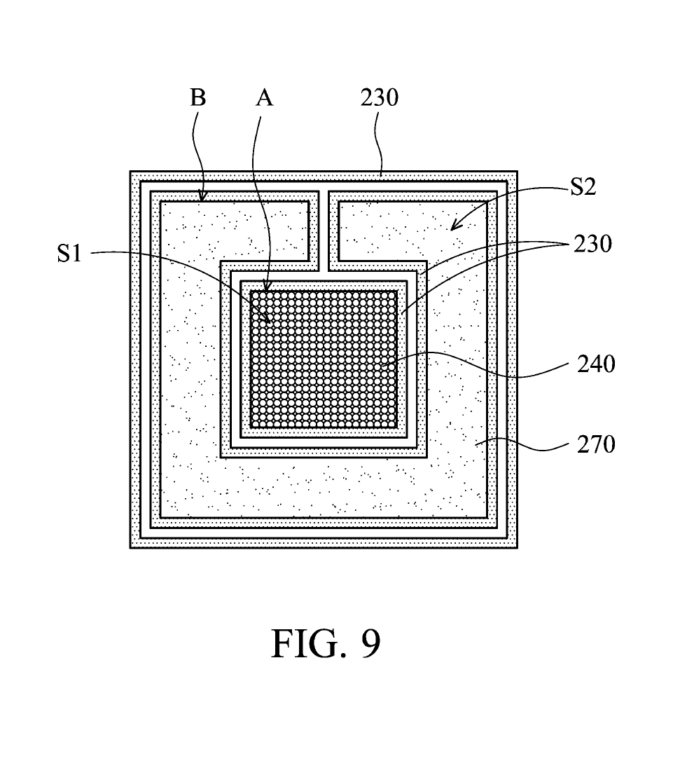

FIG. 9 is a cross-sectional view of a complex dye-sensitized photovoltaic apparatus of another embodiment of the invention. In another embodiment, as shown in FIG. 9, the positions of the first electrochromic solution 270 and the photoelectric conversion layer 240 may be exchanged, such that the first electrochromic solution 270 surrounds the photoelectric conversion layer 240.

Specifically, the positions of the first chamber S1 and the second chamber S2 may be exchanged, such that the first chamber 51 accommodating the photoelectric conversion layer 240 is located in the center area A, and the second chamber S2 accommodating the first electrochromic solution 270 is located in the peripheral area B.

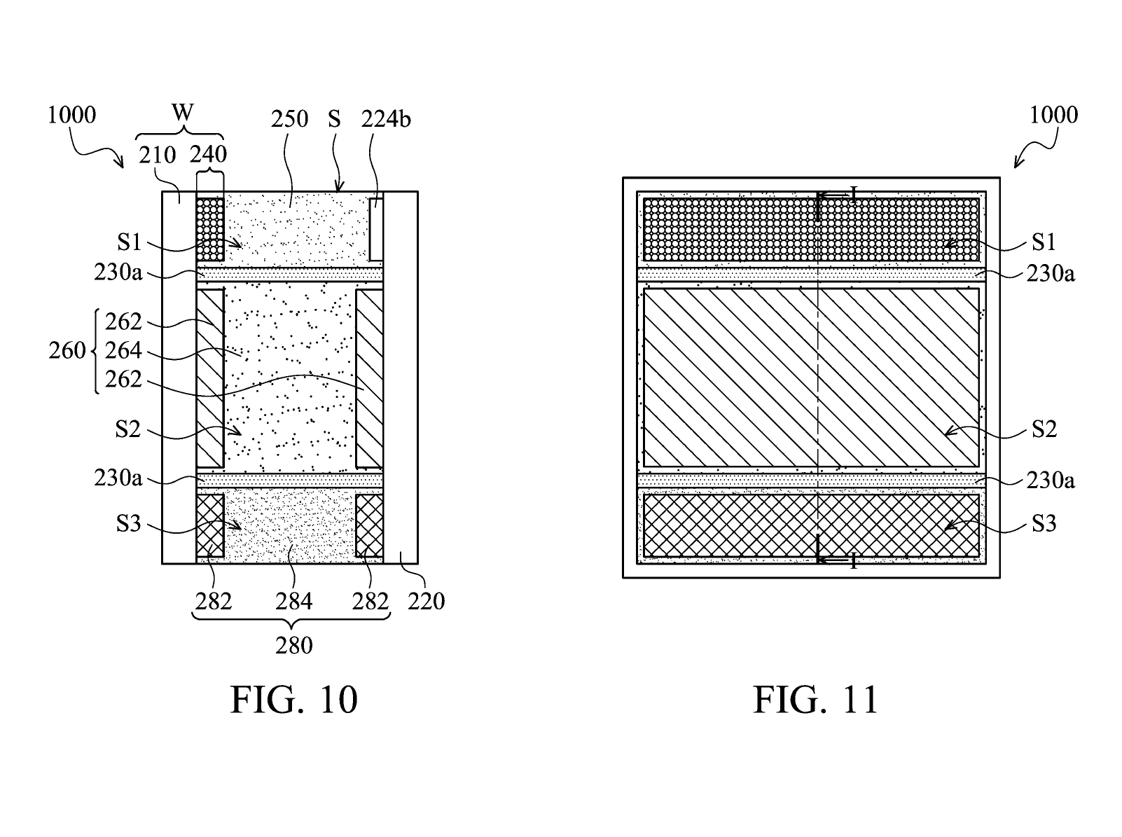

FIG. 10 is a cross-sectional view of a complex dye-sensitized photovoltaic apparatus of an embodiment of the invention. FIG. 11 is a top view of the complex dye-sensitized photovoltaic apparatus in FIG. 10, wherein FIG. 10 is a cross-sectional view along the line I-I in FIG. 11. Referring to FIG. 10 and FIG. 11, the complex dye-sensitized photovoltaic apparatus 1000 of the present embodiment is similar to the complex dye-sensitized photovoltaic apparatus 200 of FIG. 2, and the difference therebetween is that the partition member 230a of the complex dye-sensitized photovoltaic apparatus 1000 divides the space S between the conductive substrate 210 and the counter electrode 220 into a first chamber S1, a second chamber S2, and a third chamber S3, wherein the devices accommodated by the first chamber S1 and the second chamber S2 may be the same as the devices accommodated by the first chamber S1 and the second chamber S2 of the complex dye-sensitized photovoltaic apparatus 200 of FIG. 2.

The third chamber S3 may accommodate a second charge storage device 280. The second charge storage device 280 includes a second charge storage layer 282 and a third electrolyte solution 284, wherein the second charge storage layer 282 may be optionally disposed on the conductive substrate 210, the counter electrode 220, or both the conductive substrate 210 and the counter electrode 220 (as shown in FIG. 10). The third electrolyte solution 284 fills the third chamber S3 to contact with the second charge storage layer 282, wherein the third electrolyte solution 284 is different from the first electrolyte solution 250.

The use of the second charge storage device 280 may be similar to the use of the first charge storage device 260 mentioned above, and the materials of the second charge storage layer 282 and the third electrolyte solution 284 may be similar to the materials of the first charge storage layer 262 and the second electrolyte solution 264 mentioned above, thus, reference may be made thereto. The second charge storage device 280 may be the same as or different from the first charge storage device 260.

In one embodiment, the first charge storage device 260 is an electrochromic device, the first charge storage layer 262 is an electrochromic material layer, the second charge storage device 280 is a capacitor device, and the second charge storage layer 282 is a capacitor electrode.

Although FIG. 10 depicts the case that the first charge storage layer 262 is both on the conductive substrate 210 and the counter electrode 220, these are merely examples and are not intended to be limiting. Similarly, although FIG. 10 depicts the case that the second charge storage layer 282 is both on the conductive substrate 210 and the counter electrode 220, these are merely examples and are not intended to be limiting.

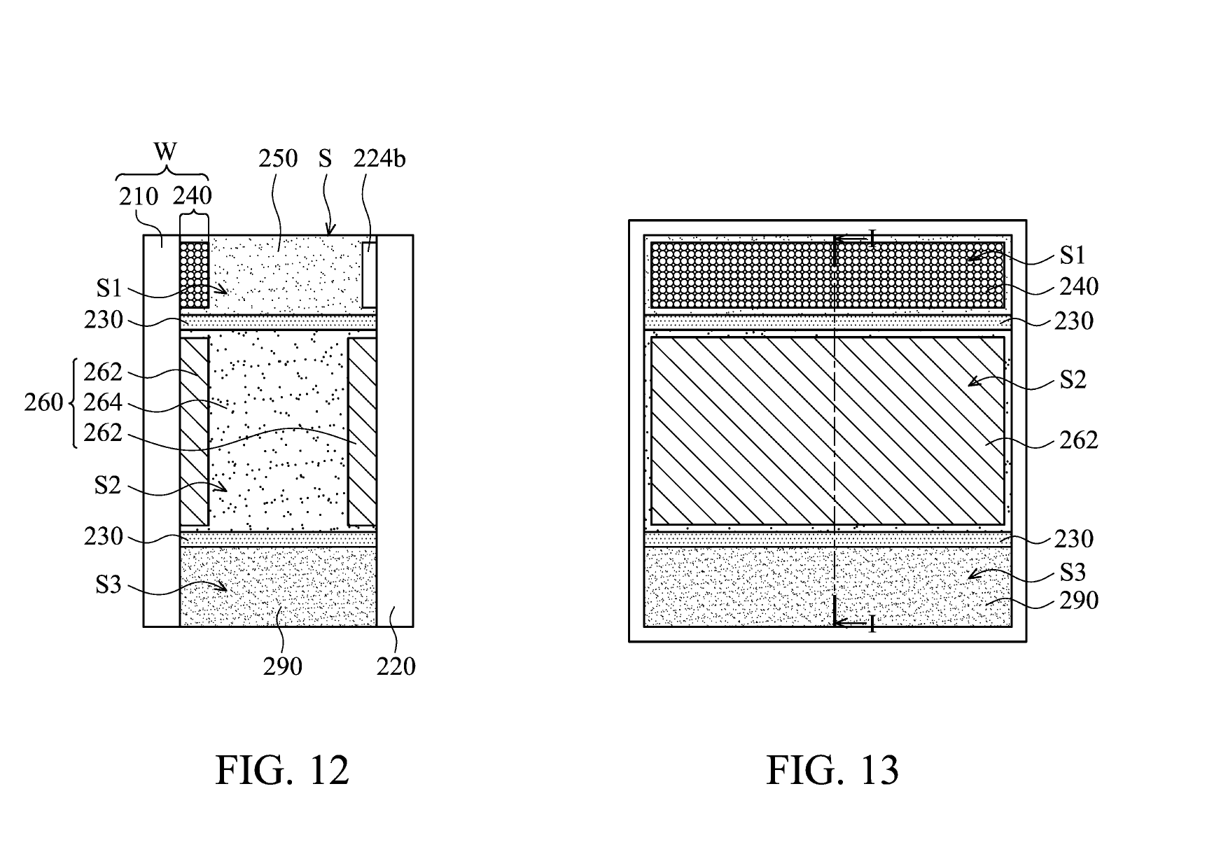

FIG. 12 is a cross-sectional view of a complex dye-sensitized photovoltaic apparatus of an embodiment of the invention. FIG. 13 is a top view of the complex dye-sensitized photovoltaic apparatus in FIG. 12, wherein FIG. 12 is a cross-sectional view along the line I-I in FIG. 13. Referring to FIG. 12 and FIG. 13, in one embodiment, the second charge storage device in the third chamber S3 may be replaced with a second electrochromic solution 290, and the second electrochromic solution 290 fills the third chamber S3 to contact with the conductive substrate 210 and the counter electrode 220, wherein the second electrochromic solution 290 is different from the first electrolyte solution 250. Reference may be made to the materials of the first electrochromic solution 270 in the embodiment of FIG. 7 mentioned above for the materials of the second electrochromic solution 290.

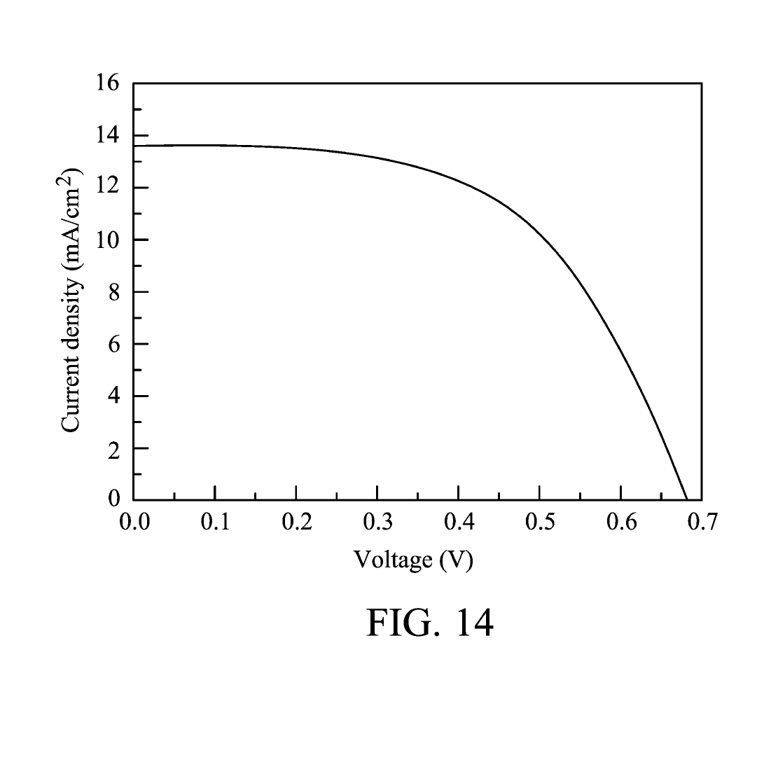

FIG. 14 is a current-voltage character curve (I-V curve) diagram of the dye-sensitized solar cell of the complex dye-sensitized photovoltaic apparatus of FIG. 2. Referring to FIG. 14, a photoelectric conversion efficiency measuring system used in a test included a solar simulator and a multifunctional digital source meter (Keithley photoelectric conversion layer 2400). Firstly, the power of the solar simulator was adjusted to be 100 mW/cm², and then the packaged complex dye-sensitized photovoltaic apparatus was disposed under a light source of the solar simulator to measure photoelectric conversion efficiency.

In the complex dye-sensitized photovoltaic apparatus used in the test, the conductive substrate included fluorine-doped tin oxides/glass, the counter electrode included fluorine-doped tin oxides/glass, the photoelectric conversion layer included titanium dioxides, and the first electrolyte solution included 0.1M LiI, 0.05M I₂, 0.6M 1,2-dimethyl-3-propylimi-dazolium iodide (DMPII), and 0.5M 4-tert-butylpyridine (TBP) dissolved in methoxypropionitrile.

The measuring scan voltage range of the Keithley photoelectric conversion layer 2400 was from 0V to −0.8V. The scan rate was 100 mV/s. The delay time was 100 ms. The current produced by the dye-sensitized solar cell at each voltage was recorded to produce the I-V curve diagram. It could be known from the I-V curve diagram that, the open-circuit voltage (V_{∝}) was 0.68V, and the short-circuit current density (J_{sc}) was 13.7 mA/cm². Meanwhile, by calculating the test result, the fill factor (FF) was 0.55, and the photoelectric conversion efficiency (η) was 5.2%.

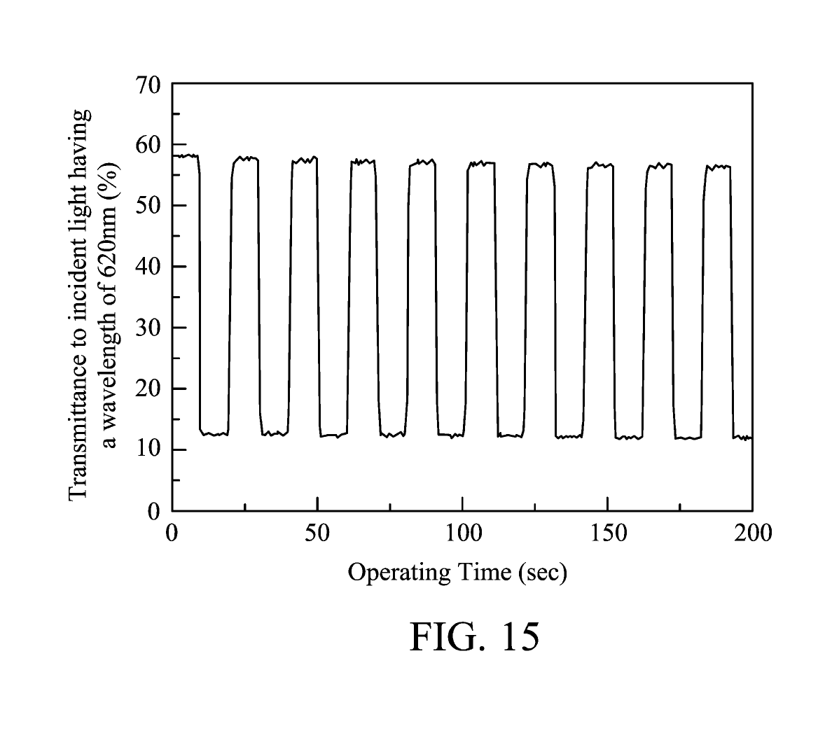

FIG. 15 is a diagram illustrating the transmittance variation of the charge storage device (the electrochromic device) of the complex dye-sensitized photovoltaic apparatus of FIG. 2. Referring to FIG. 15, in the test, bleaching processes and coloring processes were performed to the electrochromic device, and a UV light-visible light photometer was used to measure the variation of the transmittance of the electrochromic device transmitted by the incident light with a wavelength of 620 nm as operating time was increased.

In the complex dye-sensitized photovoltaic apparatus used in the test, the conductive substrate included fluorine-doped tin oxides/glass, the counter electrode included fluorine-doped tin oxides/glass, the first charge storage layer (the electrochromic layer) included PPropOT-Et₂ (poly(3,3-diethyl-3,4-dihydro-2H-thieno-[3,4-b][1,4]dioxepine)), and the second electrolyte solution included 1.0M tetrabutylammonium bromide (TBABr), 0.1M LiClO₄, and 0.004M Br₂ dissolved in 3-methoxypropionitrile.

The test results are described as follows. The bleaching time (τ_{b}) was 2.11 s. The coloring time (τ_{d}) was 1.27 s. The transmittance (T_{b}) in the bleaching condition was 57.9%. The transmittance (T_{d}) in the coloring condition was 12.4%. The transmittance difference (ΔT) between the bleaching condition and the coloring condition was 45.5%.

In view of the foregoing, in the present invention, the partition member was disposed between the conductive substrate of the working electrode and the counter electrode, so as to form a plurality of independent chambers, such that the dye-sensitized solar cell device and the charge storage device was disposed in different chambers respectively. Thus, each device may be equipped with the most suitable electrolyte, which avoids the conventional problems where the electrolytes used for different purposes are mixed and interfere with each other. Thus, the performance of each device in the present invention is improved.

Furthermore, in the present invention, the different devices are disposed in the different independent chambers respectively, which avoids the conventional problems where the photoelectric conversion layer overlaps with the electrochromic layer. Thus, the maximum transmittance of the complex dye-sensitized photovoltaic apparatus of the present invention may be effectively risen, which improves the color change effect of the electrochromic layer.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A complex dye-sensitized photovoltaic apparatus, comprising:
a conductive substrate;
a counter electrode opposite to the conductive substrate, wherein a space is provided between the counter electrode and the conductive substrate;
a partition member disposed between the conductive substrate and the counter electrode, dividing the space into a plurality of independent chambers including at least a first chamber and a second chamber, wherein the partition member comprises an insulating material;
a photoelectric conversion layer disposed on the conductive substrate in the first chamber, wherein the photoelectric conversion layer comprises a porous semiconductor layer and a dye absorbed on the porous semiconductor layer, wherein the photoelectric conversion layer and the conductive substrate form a working electrode;
a first electrolyte filled in the first chamber; and
a first charge storage device or a first electrochromic solution located in the second chamber,
wherein the first charge storage device includes a first charge storage layer and a second electrolyte, wherein the first charge storage layer is disposed on at least one of the conductive substrate and the counter electrode, and the second electrolyte fills the second chamber to contact with the first charge storage layer, provided that the second electrolyte is different from the first electrolyte, or
the first electrochromic solution fills the second chamber to contact with the conductive substrate and the counter electrode, provided that the first electrochromic solution is different from the first electrolyte.

2. The complex dye-sensitized photovoltaic apparatus as claimed in claim 1, wherein the first charge storage device is a capacitor device, and the first charge storage layer is a capacitor electrode.

3. The complex dye-sensitized photovoltaic apparatus as claimed in claim 1, wherein the first charge storage device is an electrochromic device, and the first charge storage layer is an electrochromic material layer.

4. The complex dye-sensitized photovoltaic apparatus as claimed in claim 1, wherein the counter electrode includes a substrate and a conductive layer deposited on the substrate, and the conductive layer comprises metal, carbon, or conductive polymer.

5. The complex dye-sensitized photovoltaic apparatus as claimed in claim 4, wherein the first charge storage device is an electrochromic device, the first charge storage layer is an electrochromic material layer, and the electrochromic material layer and the conductive layer both comprise the conductive polymer.

6. The complex dye-sensitized photovoltaic apparatus as claimed in claim 1, wherein the chambers further comprises a third chamber, and the complex dye-sensitized photovoltaic apparatus further comprises:
a second charge storage device or a second electrochromic solution located in the third chamber,
wherein the second charge storage device includes a second charge storage layer and a third electrolyte, wherein the second charge storage layer is disposed on at least one of the conductive substrate and the counter electrode, and the third electrolyte fills the third chamber to contact with the second charge storage layer, provided that the third electrolyte is different from the first electrolyte, or
the second electrochromic solution fills the third chamber to contact with the conductive substrate and the counter electrode, provided that the second electrochromic solution is different from the first electrolyte.

7. The complex dye-sensitized photovoltaic apparatus as claimed in claim 6, wherein the first charge storage device is an electrochromic device, the first charge storage layer is an electrochromic material layer, the second charge storage device is a capacitor device, and the second charge storage layer is a capacitor electrode.

8. The complex dye-sensitized photovoltaic apparatus as claimed in claim 1, wherein the space comprises a central area and a peripheral area surrounding the central area, the first chamber is located in the peripheral area, the second chamber is located in the central area, the first charge storage device is an electrochromic device, and the photoelectric conversion layer surrounds the electrochromic device or the first electrochromic solution.

9. The complex dye-sensitized photovoltaic apparatus as claimed in claim 1, wherein the space comprises a central area and a peripheral area surrounding the central area, the first chamber is located in the central area, the second chamber is located in the peripheral area, the first charge storage device is an electrochromic device, and the electrochromic device or the first electrochromic solution surrounds the photoelectric conversion layer.

10. The complex dye-sensitized photovoltaic apparatus as claimed in claim 1, wherein the conductive substrate comprises:
a transparent substrate having a surface facing the space; and
a transparent conductive layer disposed on the surface.
